(19) United States
(12) Patent Application Publication
(10) Pub. No.: US 2013/0301361 A1
(43) Pub. Date: Nov. 14, 2013

(54) ROW DRIVER ARCHITECTURE

(71) Applicants: Chiara Missiroli, Concorezzo (MI) (IT); Diego Della Mina, Colle Brianza (LC) (IT)

(72) Inventors: Chiara Missiroli, Concorezzo (MI) (IT); Diego Della Mina, Colle Brianza (LC) (IT)

(73) Assignee: Elpida Memory, Inc., Tokyo (JP)

(21) Appl. No.: 13/468,795

(22) Filed: May 10, 2012

(51) Int. Cl. G11C 16/06; G11C 5/14

(52) U.S. Cl. 365/185.23; 327/530

(57) ABSTRACT

Devices and circuits for row driver in a memory device. The proposed row driver circuit architectures may reduce size of the row driver circuitry and enhance the row driver circuit's reliability. Specifically, the proposed embodiments of the row driver may reduce the required sizing of the boosting capacitor or alternatively eliminate the boosting capacitor entirely. Further, the embodiments of the row driver may reduce the risk of charge-leakage on K-nodes, enhancing the row driver's reliability in driving the x-path of the memory array.

### FIELD OF THE DISCLOSURE

This disclosure generally relates to techniques and circuits for non-volatile memory devices, particularly NAND memory devices. In an exemplary embodiment, it relates to techniques and circuits for a row driver circuitry in a memory device.

### BACKGROUND

The NAND memory market in recent years has demanded higher and higher density requirements than it had before in order to support an aggressive technology scaling. The scaling of the standard NAND technology has become more challenging than it was before due at least to the reduced cell pitch (smaller memory size), because the reduced cell pitch may give rise to some undesired parasitic coupling effects. One of these is a floating-gate coupling effect. The floating gate coupling is related to interferences caused from neighbouring memory cells as they are being programmed. The interferences may prevent a proper reading of the disturbed memory cells. This phenomenon is related to the reduced memory size, because the reduced memory size may likely result in a relatively short floating gate distance either or both in the x and y directions in the memory cells. This shortened floating gate distance contributes to the worsening of this parasitic floating-gate coupling effect.

However, the demand for a higher scaling capability without compromising the reliability of the circuit operation has recently led to the development of a new charge trap technology. This new charge trap technology can avoid the above-explained floating gate coupling effect problem and make possible a scalable matrix array at the same time. Following this high array scaling technology, new challenges keep arising such as a demand for further reduction of the core-circuitry area, and various other constraints to the designing of the memory array are becoming tighter and tighter.

FIG. 1 shows an example of a NAND memory device. In particular, this disclosure is directed to block 11 of the memory device in FIG. 1—that is, a row driver circuitry of the memory device. The disclosed row driver circuitry may allow both a saving of the circuit area for the memory device as well as an efficient x-path core driving of the high voltages.

FIG. 2 shows a simplified NAND memory circuit architecture. Block shown in FIG. 2 is also shown in the matrix 16 of FIG. 1 and denoted by 16b. A NAND memory array is divided into stacks, and each stack includes a number n of cells in series. There are two selectors, one for the source side, SSG, and another for the drain side, SDG. These multiple stacks are connected to the same bit line on the y-direction (not shown). This same structure is then repeated on the x-direction to provide a full-page size, which is the portion of the memory array that is addressed at a time, for example, for a reading or program operation. Each memory array is divided into a number M of blocks that includes one stack for each bit line. The lines in x-direction connect together the gates of the memory cells, and these lines are called word lines, WL[0]˜WL[n]. A page is constituted of cells connected by the same word line.

Blocks are addressed independently by selection and represent a minimum area in the memory cells that can be biased for each one operation (e.g., erase, program, read). The circuitry configured to bias a block in the x-direction of the memory array, SSG, SDG and word lines is called a ‘row driver circuitry.’

Different row driving architectures have been developed until now in order to deliver correct voltages onto the x-axis path of the memory array. However, the design of an efficient row-driver circuitry may usually encounter some design limitations or technology constraints—for example, it may be required that the size of a row driver circuit in the y-direction to not exceed the size of a stack in the matrix array. This requirement may exist at least when the row driver circuitry is positioned on one side of the driven block and this row driver circuitry is repeated in the y-direction for each block. In effect, the size of a row driver circuit is designed to match the size of each block, and accordingly, a reduction in the size of a row driver may bring about a huge impact on the rest of the memory circuitry and thus may not be easy to implement.

Furthermore, it may be required for a row driver circuitry to ensure that the word lines are capable of being driven to a very high voltage level that, for example, may be necessary to carry out a program operation.

FIG. 3 shows voltage driving architecture in a NAND memory. As shown in FIG. 3, word lines, SSG and SDG selectors (see FIG. 2) may be biased through ultra-high-voltage pass transistors with their gates connected to each other and driven by a same signal. The node connecting these gates of the pass transistors is called the ‘K-node.’ When a block is selected for a program operation, for example, the gates of these pass transistors should be biased to a voltage level which is at least a threshold higher than the voltage level required for the program operation, wherein the k node voltage level is usually higher than what is be passed onto the selected word lines.

Considering that higher the voltage being passed onto the word lines higher the voltage at which the memory cells are programmed, it may be required to pass to selected word lines a voltage level higher than what is actually feasible to be driven on these selected word lines. The technical limitation imposed on the voltage level as being physically feasible to be driven onto the selected word lines may depend on the maximum voltage applicable to the gates of the pass transistors of the K-node. This maximum voltage is the highest voltage level that can be applied to the pass transistors without exceeding the break-down voltage of their gate oxide, and further, the maximum voltage level also has a ceiling limit of the junction break-down voltage of the involved circuitry. For example, if the selected block's K-node is biased to the limit of the break-down voltage, the selected word line can be biased to a voltage that is equal to the break-down voltage minus the transistor's threshold voltage. Here, it may be noted that the threshold voltage of the transistor may relatively high due to a body effect.

On the other hand, the K-node may not be able to be biased via switches or pass transistors to the limit of the break-down voltage unless high-voltage p-mos transistors are supplied. Since NAND technology may not provide these high voltage p-mos transistors, the voltage to be applied onto the K-node may be produced locally by various boosting techniques. For example, a block decoding circuitry produces an enable logic signal for each row driver circuit on the basis of the address selection, and then the selected row driver may ensure to bias the K-node at a properly high voltage level when the enable logic signal is activated.

Typically, the state-of-art row drivers may employ a pass transistor on each word line of the memory array but uses different techniques to deliver to the gates of the memory array cells a voltage that is high enough to turn on the cells. Further, they attempt to ensure passing of a sufficiently high voltage onto the memory arrays, the high voltage being required for a selected operation such as a program operation. In fact, there has been multiple attempts done in the art to address the above-identified design limitations for a row driver circuitry, and among many, two row driving circuitries will be described herein. These two row driving circuitries are selected for description solely for the convenience of the description of the proposed row driving circuitries and may not be used to limit in any way the scope of the proposed row driving circuitries and methods thereof.

Specifically, the selected two row driving circuitries can help illustrate two specific areas in the state-of-art row driving circuit designing technology that may merit an improvement—these two areas are (1) K-node leakage issue and (2) sizing of the row driver circuitry.

(1) K-Node Leakage

The first type of the state-of-art row driver circuitry discloses what is called a self-boosting technique. The gates of the pass transistors are all connected to the same node, which is called a K-node. This K-node may have a very low capacitance such that pre-charging this node to a voltage level equal to or lower than a voltage level to be passed onto the memory array and subsequently isolating this K-node would be sufficient to turn on the pass transistors when the drain voltage of the pass transistors rises. This occurs due to the parasitic capacitance between the gates of the pass transistors and other terminals, and more specifically this parasitic capacitance is high and significant with respect to the total capacitance of the K-node. Accordingly, this parasitic capacitance can, in effect, boost the K-node. This is called the self-boosting technique.

One aspect of this self-boosting technique that can merit an improvement may be a row driver circuit with the self-boosting technique can become very sensitive to any leakages occurring at the K-node. That is, the K-node should be controlled tightly to minimize any charge leakages to the extent possible, and transistors should not be kept at an on-state for too long a time. The reasons for these characteristics are now explained in more detail with references to specific row driver circuit schematic.

A row driver circuit with the self-boosting technique as explained above is now described in more detail with reference to FIGS. 4 and 5.

FIG. 4 shows an example of the state-of-art row driver circuit architecture with the self-boosting technique. This circuit is implemented using only ultra-high-voltage n-mos transistors without high-voltage p-mos transistors. FIG. 5 shows an example of the driving sequence of the row driver in FIG. 4 during a program operation.

In FIG. 4, the K-node is precharged through the pass transistors, SELXa and SELXb. The gates and drains of these K-node pass transistors are driven to a high voltage level (e.g., 20V) in order to precharge the K-node at a high voltage level (e.g., 15V). SELXb transistor may not always be necessary, and its presence may depend on the array dimensions and driving capabilities of the circuitry configured to bias the A_GVX node. The purpose of the SELXb transistor may be to precharge the K-nodes of only a portion of the memory array—so as to reduce the dynamic power consumption of the A_GVX line. One or more transistors could be used for this purpose, which may depend on the number of the K-nodes. It may be noted, however, that any addition of these transistors can become a trade-off between the precharging of the K-nodes and the increased power consumption with a bigger sized row driving circuitry (inefficient area occupancy of the circuit).

Referring to the circuit schematic of FIG. 4, it is possible to precharge the K-nodes, for example, of only a quarter (¼) of the memory array. For the selected portions of the memory array, high-voltage decoding signals that activate the precharging process can be driven on lines A_HXA and A_HXB. These signals may be driven on an address-basis so that the K-nodes of the selected blocks can be precharged while the K-nodes of the unselected blocks are left floating. This high voltage decoding to produce the A_HXA and A_HXB signals may take up a large area and, accordingly, this high voltage decoding is placed outside the core circuitry area. The A_HXA and A_HXB signals may be delivered to a row driver circuit by a metal connection which passes through the entire row driver circuitry.

Further, introducing an additional level of a local high-voltage decoding inside the core circuitry of the row driver can occupy a large area since additional transistors should be placed in series with SELXA and SELXB and driven from the high voltage decoding placed outside the core row-driver circuitry. This can provide reasons for why the number of pass transistors such as SELXA and SELXB in FIG. 4 may not be high, and only a part of the high-voltage decoding can be done in the above-described way.

However, a complete block decoding may be performed by low voltage circuitry placed inside the core, near the row drivers or at least a pre-decoding can be placed outside the core and the full decoding can be completed locally. This local low voltage decoding may be much less expensive in terms of the chip area and also be placed near each row driver to produce the SELa_N signal. When the block is selected, the SELa_N signal goes low, and when the block is unselected, SELa_N line is kept at a power supply level. Before the block decoding activation, A_HXA and A_HXB signals all go to a low voltage level so as to isolate the K-nodes. Accordingly, when the low voltage decoding is activated, the unselected K-nodes are discharged through transistor MSEL. On the other hand, the K-nodes of the selected block are isolated.

The signal ERASE is kept at a low voltage level to keep the selector lines of the unselected block grounded through transistors M1 and M2. Thus, transistors M1 and M2 of the unselected bock are at an on-state, while transistors M1 and M2 for the selected block are at an off-state. Since transistors M1 and M2 are of the n-mos type, signal SELa_N is kept at low to turn off transistors M1 and M2 and signal SELa_N is kept at high to turn on the transistors M1 and M2.

At this point, the biasing voltage may be delivered to VXL<X:0>, GSELD and GSELS lines. The number of VX lines and MWL transistors may be determined based on the number of word lines inside each block. When VXL<X:0>, GSELD and GSELS lines rise, the parasitic capacitance of MWL<X:0>, MSDG and MSSG transistors boost the K-node. Thus, K-node may be boosted. As this boosting of the K-node continues, the proper voltage may be reached which would allow the memory array word lines and selector lines to be biased at the same voltage value of VXL<X:0>, GSELD and GSELS lines, respectively. The rising of the K-node by MWL<X:0> parasitic capacitance is referred as the self-boosting mechanism or self-boosting technique. This self-boosting technique may rely on the parasitic capacitance of MWL<X:0> being a major contribution to the total capacitance of the K-node. The boosting achieved on the K-node may be expressed by the following relationship:

$$Δ {V}_{K - node} = {\sum }_{k = 0}^{x} ( \frac{Δ {V}_{VX [ k ]} \cdot {Cpar}_{MXL [ k ]}}{{C}_{Ktot}} ) + \frac{Δ {V}_{GSELD} \cdot {Cpar}_{MSDG}}{{C}_{Ktot}} + \frac{Δ {V}_{GSELS} \cdot {Cpar}_{MSSG}}{{C}_{Ktot}}$$

where Cpar_{MXL}, Cpar_{MSDG}, Cpar_{MSSG} represent parasitic capacitance of the pass transistors for Vx, GSEL and SELS, respectively. C_{Ktot} represents the total parasitic capacitance of the K-node.

Transistors M1 and M2 may be used to keep the unselected block selector lines grounded so that it may be ensured that no current is sunk by the unselected blocks from the bit lines. During an erase operation, the word lines of the selected block may be grounded by biasing VXL<X:0> lines to ground while the selector lines are left floating. In order to bias WL<X:0> and leave SDG and SSG lines floating, the K-node of the selected block may be biased to VPWR, turning on MWL<X:0> and ERASE signal may be kept to VPWR together with GSELD and GSELS, turning off M1 and M2. The K-nodes for the unselected blocks may be grounded as in a read or program operation.

This row driver circuitry may be efficient in terms of the circuitry-area but may rely on the assumption that no leakage occurs on the K-nodes. For example, a sub-threshold leakage of SEL transistor could discharge the K-node of the selected block very fast since the capacitance of the K-node is too low to ensure that the self-boosting mechanism performs properly. As a consequence, this row driver circuitry may not be enabled for too long a time.

Second type of the state-of-art row driver circuitry relies on a more efficient boosting technique than the one employed in the first type row driver circuitry—that is, the second type row driver may have a better K-node charge retention mechanism. This mechanism is now explained in more detail.

In the second type row driver circuitry, a capacitor is connected to the K-node. When a high voltage is to be passed onto the memory array, the capacitance is boosted by delivering to the other side of the capacitor the same voltage that is to be passed onto the memory array. This technique may be more efficient than the previously-explained self-boosting circuit of the first type row driver, because the K-node boosting capacitance which is constituted of the K-node boosting capacitor and the parasitic capacitance of the pass transistors may become higher than the K-node capacitance of previous analyzed row driver circuit. Accordingly, the voltage driven on the gates of the pass transistors can rise much higher than in the previously-explained row driver circuitry. Furthermore, this in turn may allow a lower precharge voltage level for the K-node. On the other side, the second type row driver may require high-voltage p-mos transistors, in addition to ultra-high voltage n-mos transistors which were required in the above-explained first-type row-driver circuitry.

However, the second-type of the state-of-art row driver may still merit an improvement in one area—that is, in the second type of row driver, the K-node capacitor may take up a too large area in an integrated circuit to provide an ideal size of the chip. As a consequence, the second type of the row driver may not offer the competitive edge with respect to the sizing of the row driver circuitry.

The second type of the state-of-art row driver circuitry is now described in more detail with reference to FIGS. 6 and 7a-7b.

FIG. 6 shows an example of the second type of the state-of-art row driver circuit architecture. FIG. 7a shows an example of the driving sequence of control signals in the second type of the state-of-art row driver circuit in FIG. 6 during a program operation. FIG. 7b shows an example of the driving sequence of control signals in the second type of the state-of-art row driver circuit in FIG. 6 during an erase operation.

The basic operation of the second type of the state-of-art row driver circuitry in FIG. 6 is explained. All of the K-nodes can be precharged through elevator A. A_GVX may be set to a high voltage value (e.g., 10V), and A_HGVX may be risen to a higher value (e.g., 15V). SELa_N signal may be the decoded block selection and may be active only for the selected block. SELa_N may be low for the selected block and may discharge the gates of transistors M4 via the conductive transistor M5. Then, as a consequence, the gate of transistor M3 may be charged to A_GVX, and thus transistor M3 may be turned off. The K-node is precharged to a lower voltage value between A_GVX and A_HVGX minus a threshold.

The K-nodes of the unselected blocks may be discharged to ground through MSEL transistor, because SELa_N is high. The elevator biasing for the unselected blocks may be opposite of that of the selected block, and transistor M3 may be at an on-state while transistor M4 is turned off. Transistor M5, which is biased to power supply, may prevent the high voltage of A_GVX from being delivered to the low voltage decoding circuitry producing SELa_N signals. Due to presence of this circuitry, the precharging of the K-nodes may be limited to the ‘safe-operation-area’ constraints of the p-mos transistors.

Also, transistors M3 and M4 being high voltage transistors rather than ultra high voltage transistors such as n-mos transistors may contribute to the fact that the precharging voltage level for the K-nodes may be reduced from that of the previously-explained first type state-of-art row driver circuit architecture, since the precharging voltage level of the K-nodes in the second type row driver may not exceed the maximum voltage level that can be supplied to the p-mos transistors without break-down. In FIG. 7a, K-node is, for example, precharged at 10 volts. The transistors M3 and M4 in FIG. 7a are assumed to be incapable of charging K-node at a voltage higher than 10 volts; thus, K node is not precharged at a voltage level higher than 10 volts in this state-of-art row driver circuit. After the K-node has fully precharged, A_HGVX may be lowered to the power supply level and the K-node of the selected block can be isolated. The K-nodes of the unselected bocks may be kept at ground through MPASS and MSEL.

At this point, G_BOOST, GSELD, GSELS, VXL<X:0> may be raised to the high voltage level, and the K-node of the selected block may be boosted through the self-boosting mechanism (explained in the previous section). It can be noted that the boosting in this row driver may be driven for the most part by the capacitance of the CBOOST. The fact that the capacitance of CBOOST may be the most relevant capacitance in precharging the K-node may contribute to the high efficiencies of this row driver. That is, in this boosting mechanism, GSELD, GSELS, VX<X:0< may be passed onto SSG, SDG and WL<X:0>, respectively.

FIG. 7a shows an example of the above-described algorithm and control signals' driving sequence in a program operation. When the selected word lines are to be raised to the high programming voltage, the GBOOST node may also be raised to the same high programming voltage. This may contribute to the further charging of the K-node. Moreover, the K-node capacitance may be much higher than in the previously-explained first type row driver circuit. Further, the sub-threshold leakage of MPASS may be suppressed by the low voltage biasing of the gate and high voltage biasing of the source and drain. This way, the charge on the K-node may be retained for a longer period of time than it was the case in the first type row driver circuit, which could mean that the decoding in the second type row driver may be more reliable than that of the first type at least in some circumstances.

Further, the discharge phase may be more reliable in the second type row driver circuitry than in the first type row driver circuitry. As shown in FIG. 7a, before G_BOOST, GSELD, GSELS, VXL<X:0> discharge, the K-node is connected to the elevator by the rising signal of A_HGVX. This may allow forcing of the K-node's precharging while avoiding the snap-back effect that could be caused from the discharging lines in the first type row driver circuitry.

FIG. 7b shows an example of the above-described algorithm and control signals' driving sequence in an erase operation. As shown in FIG. 7b, it may be an improvement in this second type row driver that the K-node can be driven directly by the elevator, keeping A_HGVX at a high voltage (e.g., 10V) and A_GVX at a power supply or higher voltage level. ERASE signal may be managed as previously-explained in order to allow SDG and SSG to float. The boosting mechanism by CBOOST capacitance may not be used in this case since the biasing of the K-node to the power supply level may be enough to keep the word lines grounded through the MWL<X:0> transistors. One advantage of this row driver circuitry may be that the K-node can now be biased during the whole erase operation, instead of being left floating. Accordingly, it may now be ensured that the row driver can be enabled without time constraints, which could be caused from the charge retention of the K-nodes. This feature may become important especially during an erase operation since the time required for this operation may be much longer than the time required for other operations such as a program or read operation.

However, there may still be a draw back in this second type of the state-of-art row driver. The draw back may be related to the sizing of the row driver circuitry, which in turn may affect the sizing of the memory chip as a whole. The chip area required for the CBOOST capacitor may be significant, which may reduce the area-efficiency of the chip as a whole.

### SUMMARY

According to an embodiment, a device includes a first transistor having a source-drain path coupled between first and second nodes, the first node being coupled to a control node of a pass circuit, a second transistor coupled between the second node and a ground potential and a gate to which a selection signal is supplied, and a voltage-charging circuit including a third transistor configured to withstand a voltage that is higher than 10 volts to charge the first node.

According to another embodiment, a device includes a non-volatile memory array coupled to a data line, a data line driver driving the data line to a selection level, the data line driver comprising, a first transistor coupled between first and second nodes and a gate coupled to a first voltage line, a second transistor coupled between the second node of the first transistor and a ground potential and having a gate coupled to which a selection signal is supplied, a third transistor coupled between a second voltage line and the second node of the first transistor and having a gate to which a first control signal is supplied, a fourth transistor coupled between the second voltage line and the second node of the first transistor and having a gate coupled to the first node of the first transistor, and a fifth transistor coupled between a fourth node to which an inverted one of the selection signal is supplied and the second node of the first transistor and having a gate coupled to an erase signal.

According to still another embodiment, a device includes a non-volatile memory array coupled to a data line, a data line driver driving the data line to a selection level, the data line driver comprising, a first transistor coupled between first and second nodes and having a gate coupled to a first voltage line, a second transistor coupled between the second node of the first transistor and a third node and having a gate to which a discharge signal is supplied, a third transistor coupled between the third node of the second transistor and a ground potential and having a gate coupled to which a selection signal is supplied, a fourth transistor coupled between a second voltage line and the first node of the first transistor and having a gate to which a first control signal is supplied, a fifth transistor coupled between a third voltage line and a fourth node and having a gate coupled to the third node of the second transistor, and a sixth transistor coupled between the third voltage line and the third node of the second transistor and having a gate coupled to the fourth node of the fifth transistor; a seventh transistor coupled between the fourth node of the fifth transistor and the gate of the third transistor and having a gate to which a fourth voltage line is supplied; and a eight transistor coupled to the data line and having a gate coupled the first node of the first transistor.

### BRIEF DESCRIPTION OF THE DRAWINGS

FIG. 1 illustrates an example of a NAND memory device.

FIG. 2 illustrates an example of a simplified NAND memory circuit architecture.

FIG. 3 illustrates an example of voltage driving architecture in a NAND memory.

FIG. 4 illustrates an example of the first type state-of-art row driver circuitry.

FIG. 5 illustrates an example of the driving sequence of the row driver in

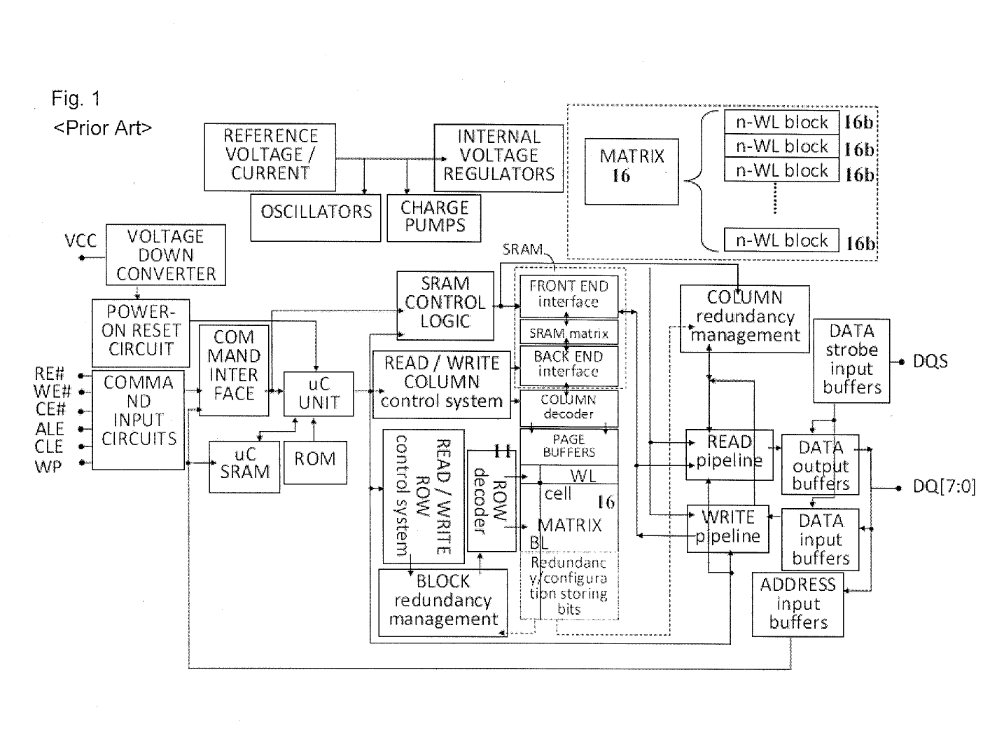

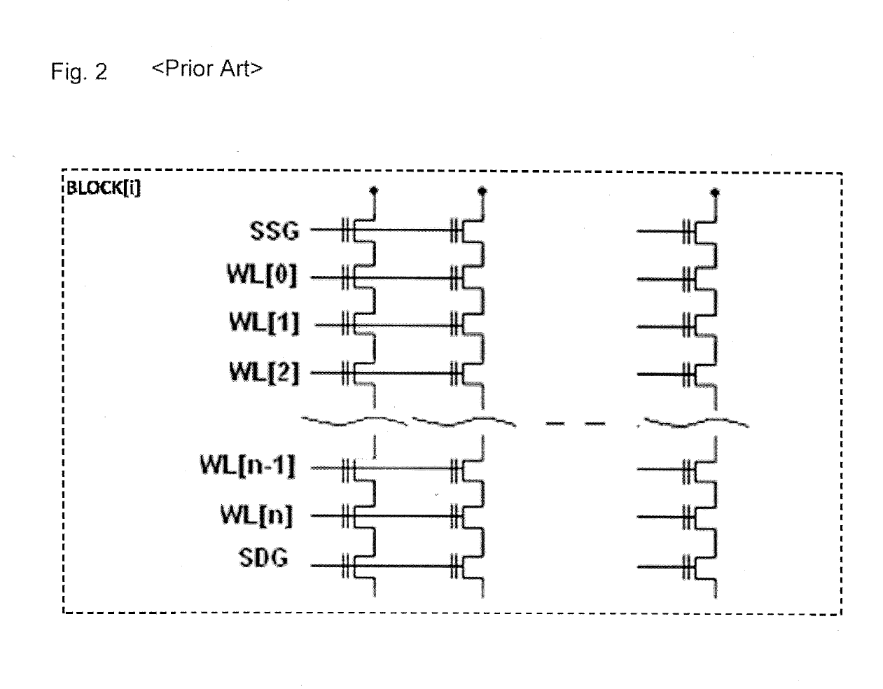

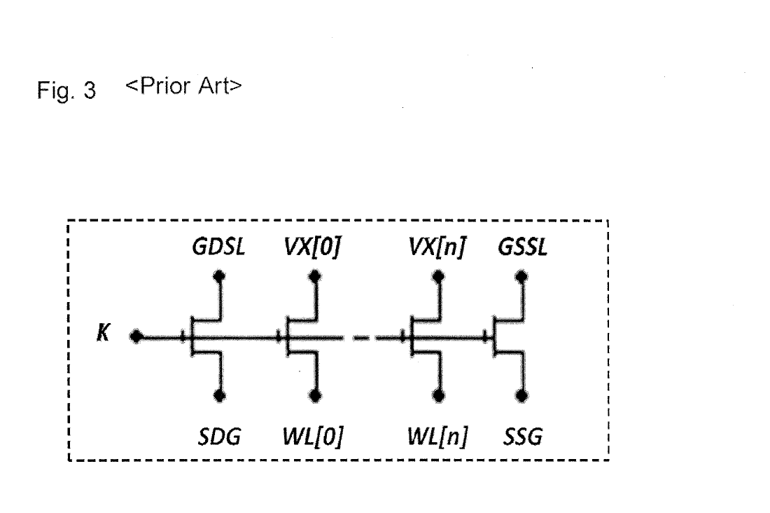

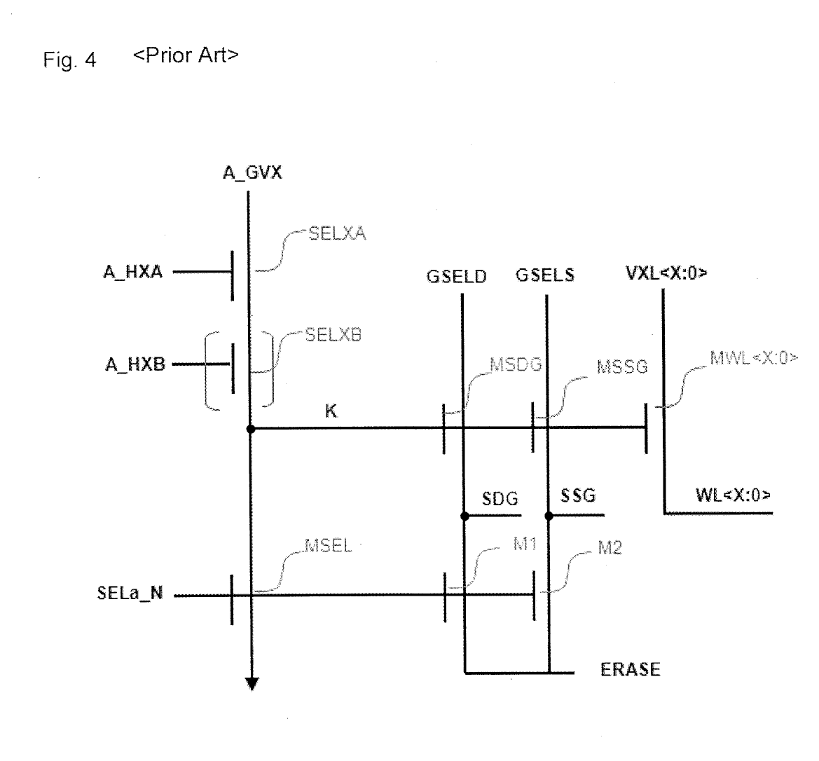

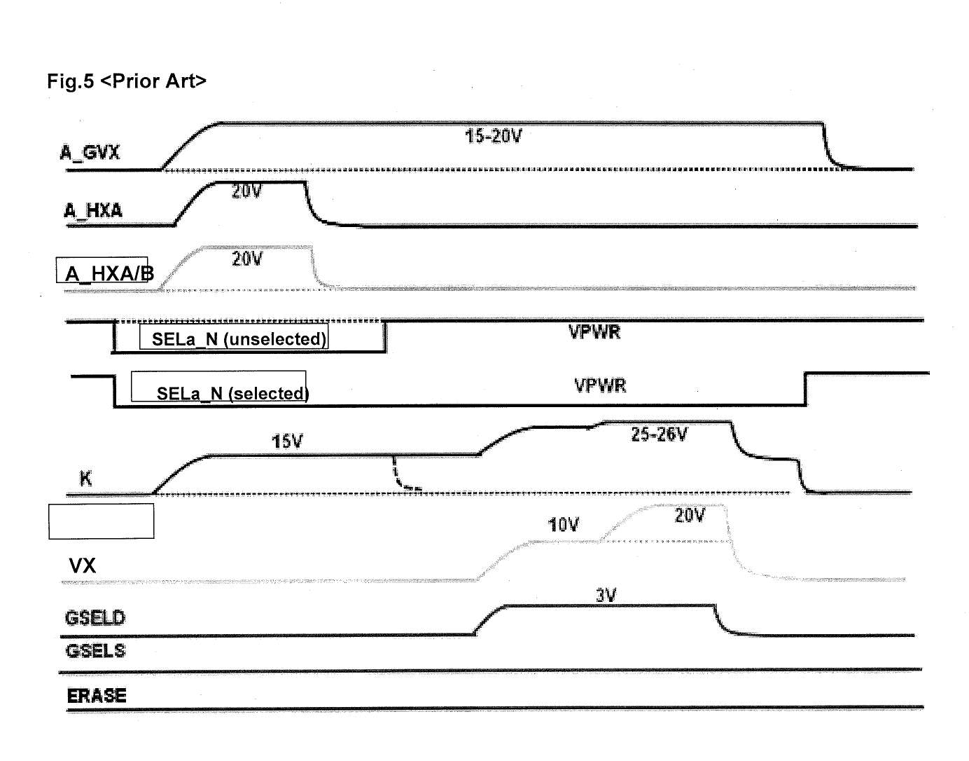

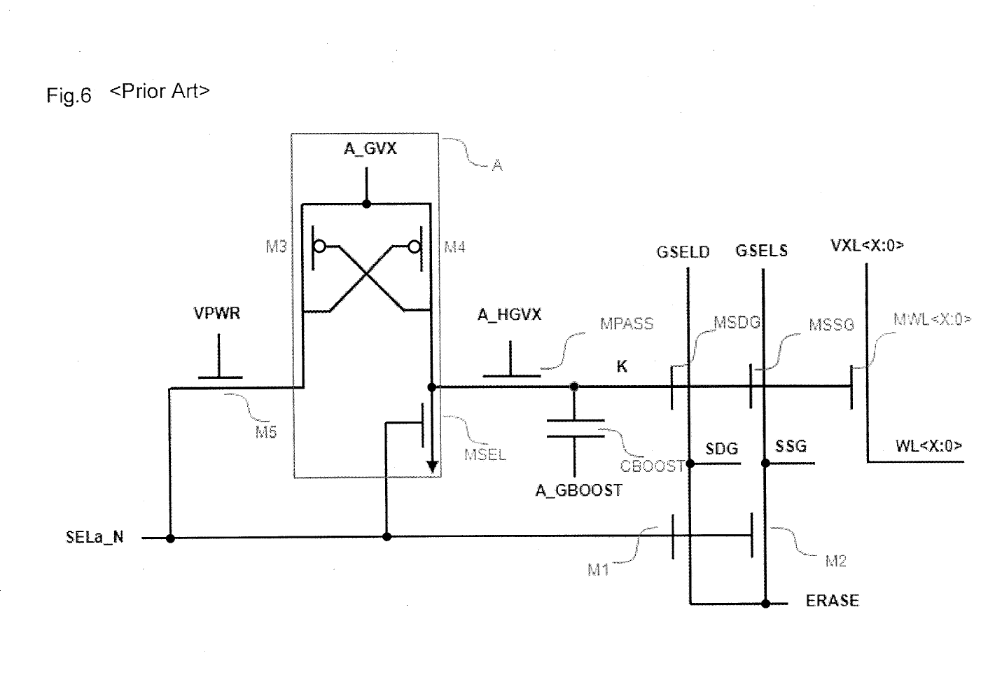

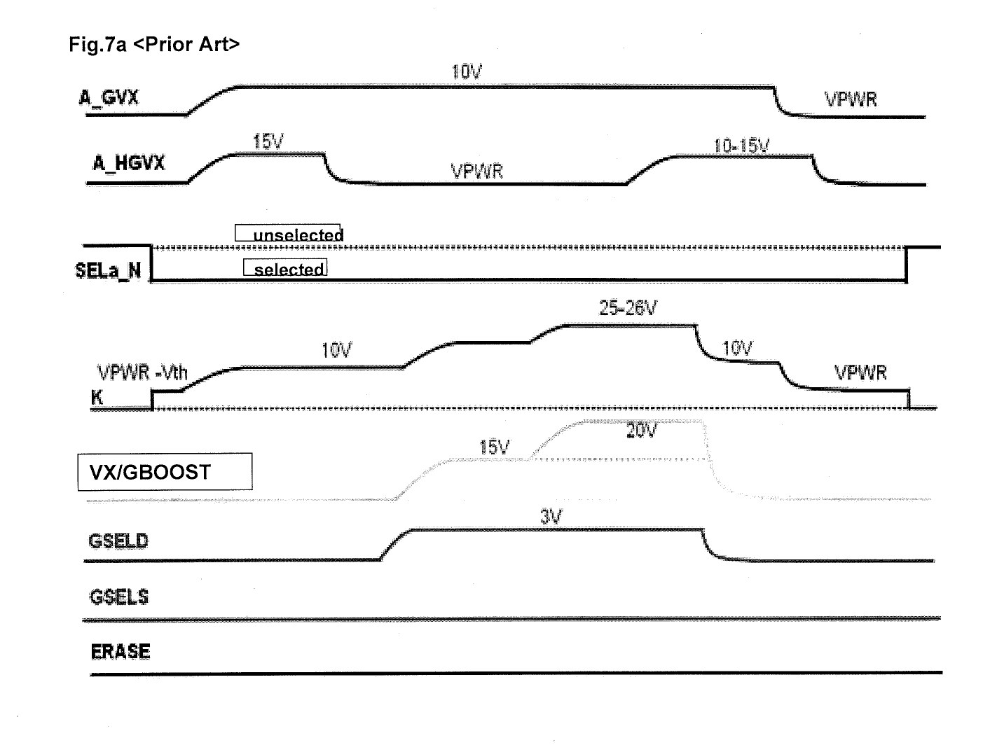

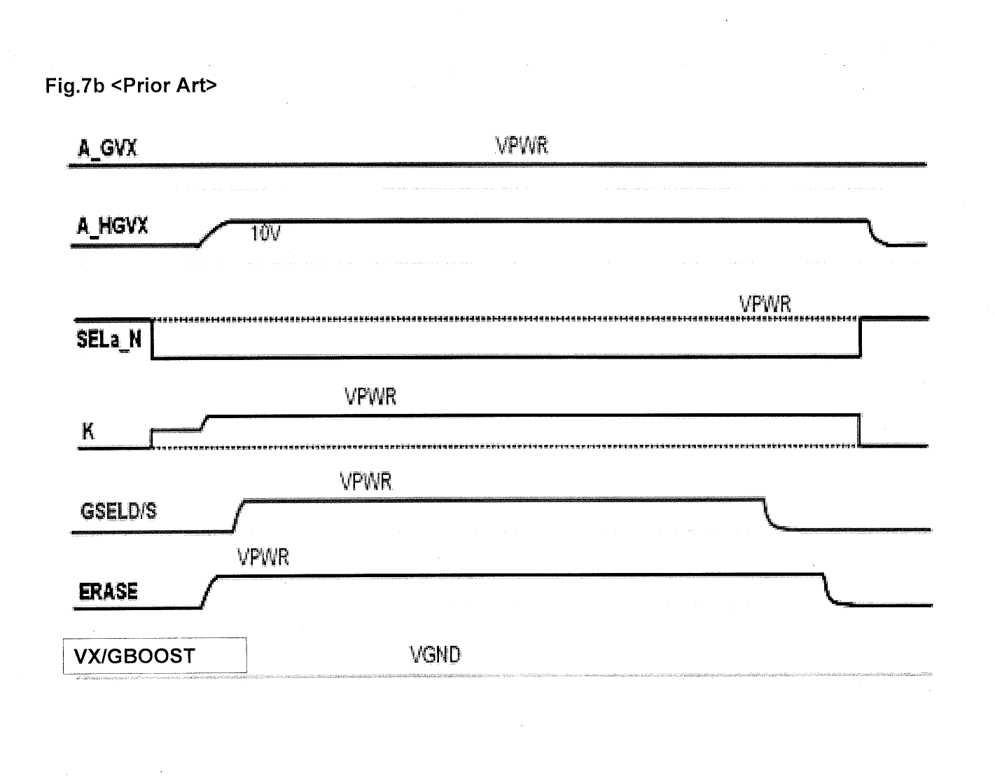

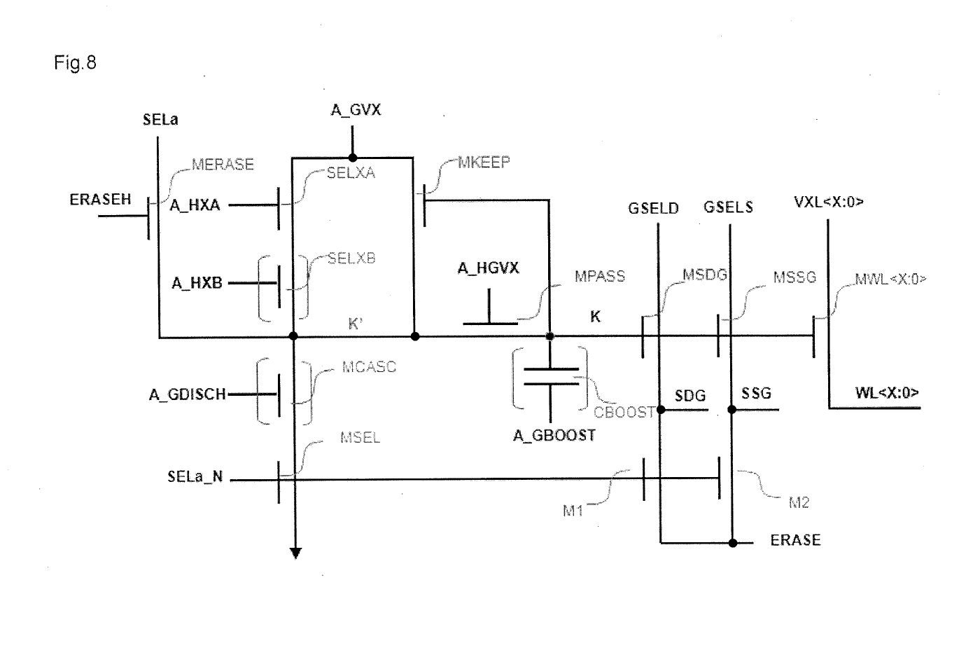

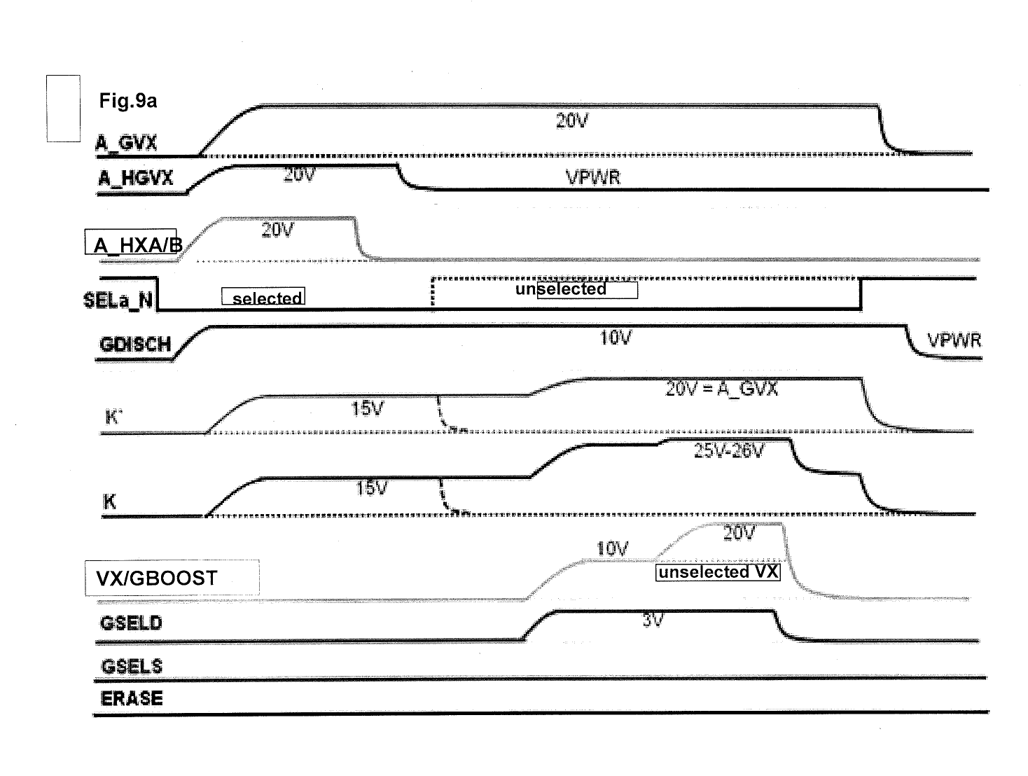

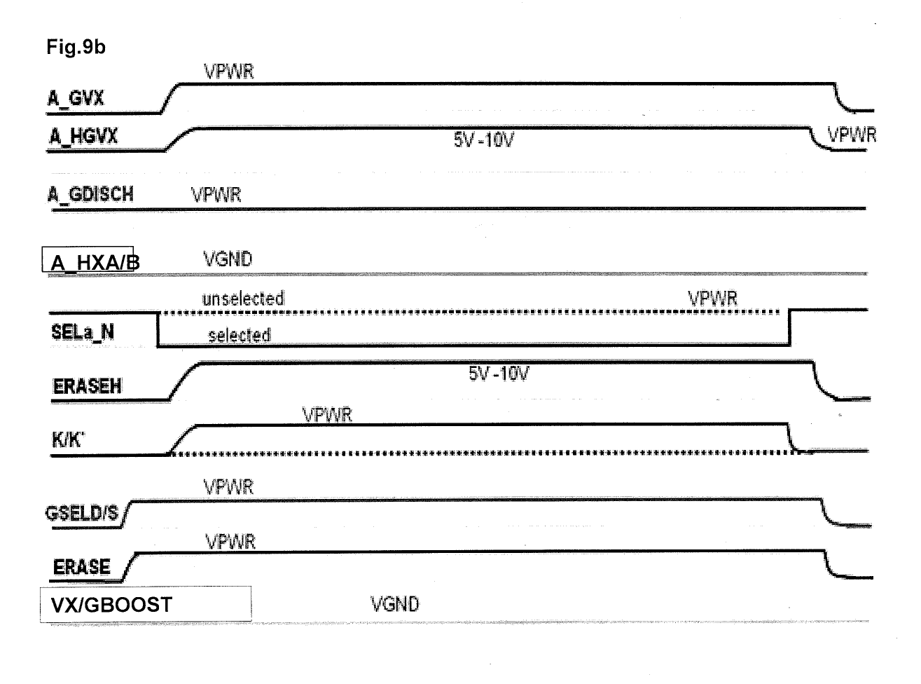

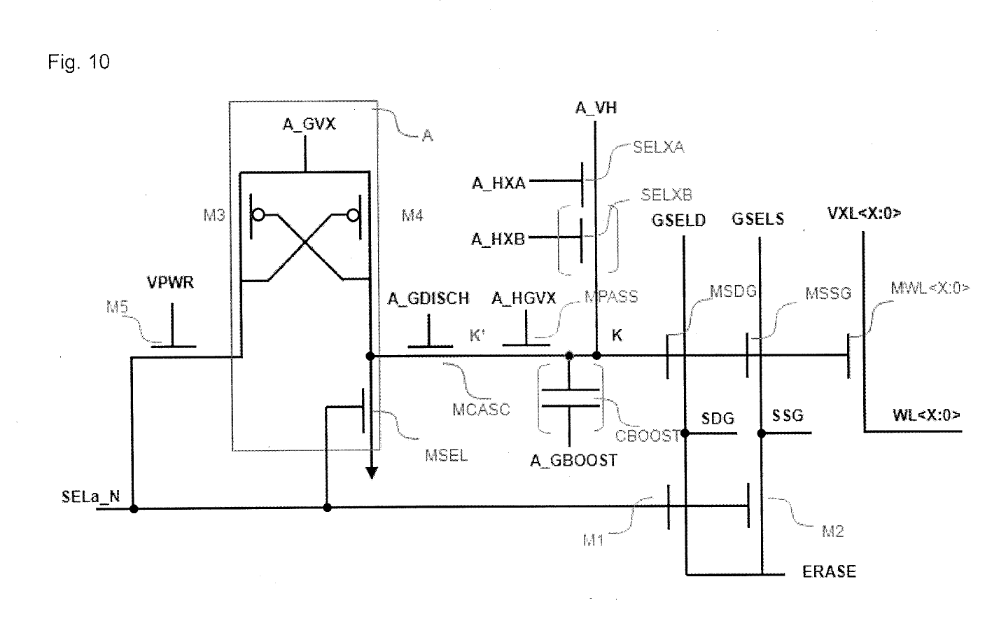

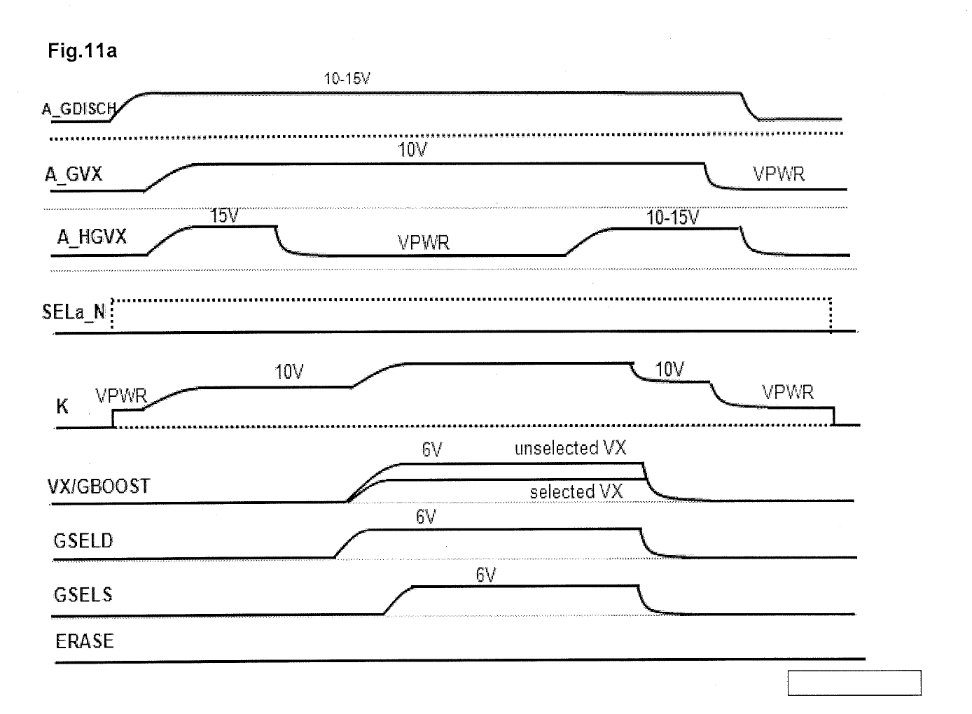

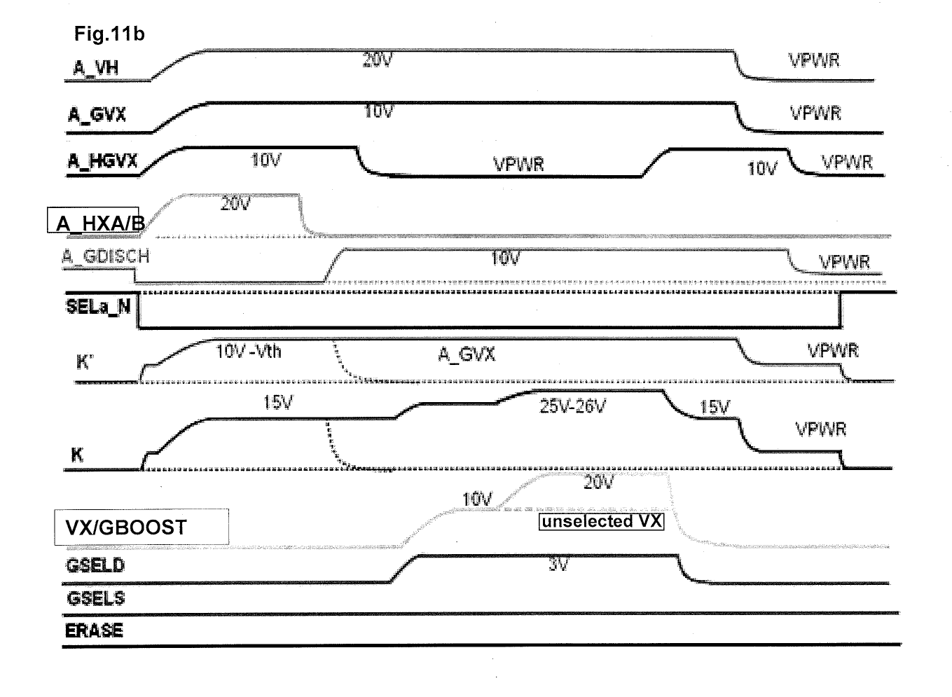

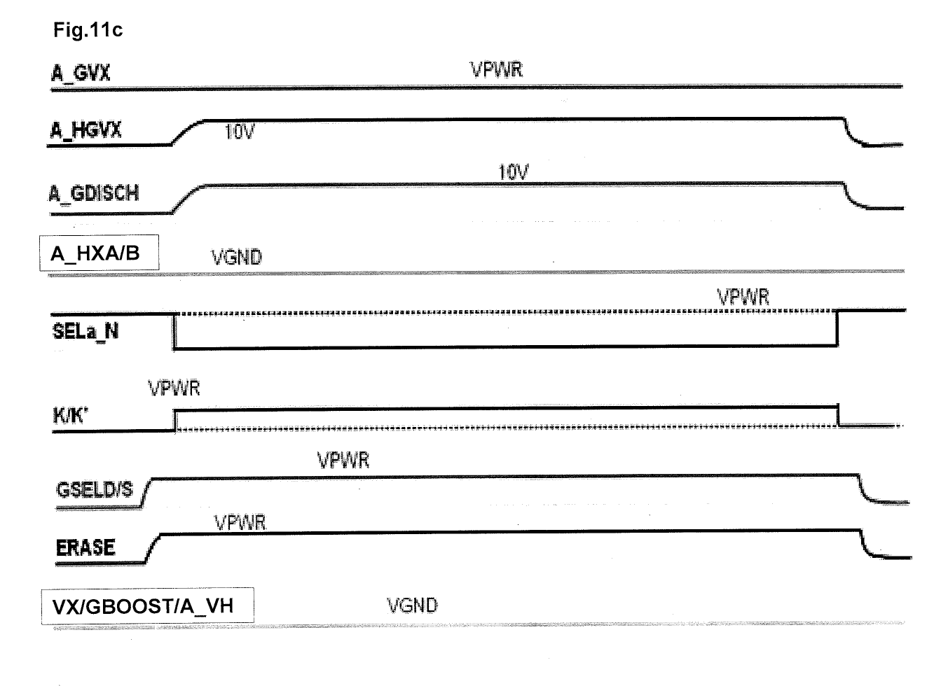

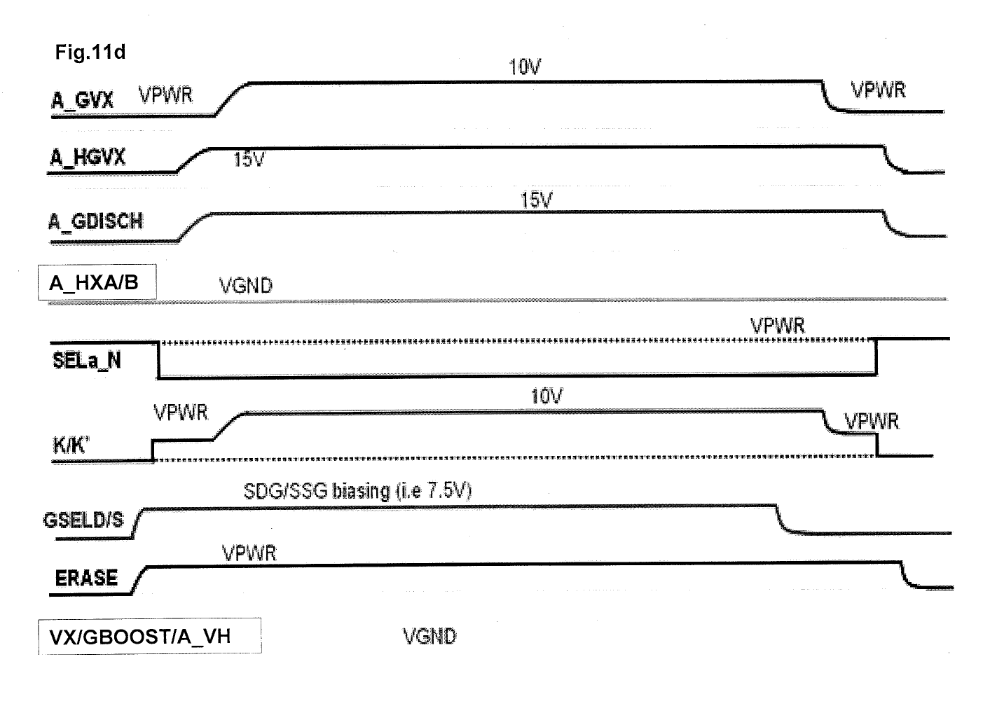

FIG. 4 during a program operation.

FIG. 6 illustrates an example of the second type state-of-art row driver circuitry.

FIG. 7a illustrates an example of the driving sequence of the row driver in FIG. 6 during a program operation.

FIG. 7b illustrates an example of the driving sequence of the row driver in FIG. 6 during an erase operation.

FIG. 8 illustrates an example of an embodiment of the proposed row driver circuitry.

FIG. 9a illustrates an example of the driving sequence of the row driver in

FIG. 8 during a program operation.

FIG. 9b illustrates an example of the driving sequence of the row driver in

FIG. 8 during an erase operation.

FIG. 10 illustrates an example of another embodiment of the proposed row driver circuitry.

FIG. 11a illustrates an example of the driving sequence of the row driver in FIG. 10 during a read operation.

FIG. 11b illustrates an example of the driving sequence of the row driver in FIG. 10 during a program operation.

FIG. 11c illustrates an example of the driving sequence of the row driver in FIG. 10 during an erase operation.

FIG. 11d illustrates another example of the driving sequence of the row driver circuit in FIG. 10 during an erase operation.

### DETAILED DESCRIPTION

The claimed subject matter will now be described herein with reference to illustrative embodiments. Those skilled in the art will recognize that many alternative embodiments can be accomplished using the teachings of this disclosure and that the claimed subject matter is not limited to the embodiments illustrated here for explanatory purposes.

Described are methods and circuits for row driver circuit architecture that may allow high precharging of the K-nodes, which can make possible to reduce the size of the CBOOST capacitor without compromising the reliability of the row driver circuit. Alternatively, the proposed row driver circuitry may eliminate the need of the CBOOST capacitor entirely, thereby capable of reducing the size of the row driver circuitry significantly. The proposed row driver circuitry may provide a technique to reduce the leakage on the K-node, thereby enhancing the reliability of the row driver. Further, the proposed row driver circuitry may also enhance the reliability in driving the x-path of the memory array to high voltage levels. The proposed row driver circuitry may achieve an enhancement in the circuit's reliability and an increase in the area-efficiency at the same time.

The above can be achieved, for example, by use of full ultra-high voltage n-mos circuitries inside the row driver. The K-node can be precharged by a pass transistor that could be turned off after the K-node has reached the gate voltage minus a threshold voltage. After the K-node has been isolated, the K-node can be boosted by the self-boosting technique. This may reduce the need of the boosting capacitor and accordingly may allow reducing the size of the boosting capacitor.

Further, as the high voltages may be passed on to not only the memory array but also the drain side of the pass transistor, these high voltages can help precharge the K-node, which may result in higher precharging of the K-nodes that it was before in the previously-explained state-of-art row driver circuitries. This high precharging of the K-nodes may help reduce the sub-threshold leakage that might occur on the K-nodes and accordingly may help achieve a more reliable K-node biasing and voltage delivering mechanism for the x-path of the memory array.

Further, the proposed row driver circuit architecture may allow not only high precharging of the K-nodes but also driving of the K-nodes for a long period of time. One embodiment of the proposed row driver circuitry may even allow driving of the K-nodes for an indefinite period of time. This feature may be useful in some circumstances.

FIG. 8 shows an example of an embodiment of the proposed row driver circuit architecture.

In a broad sense of the circuit shown in FIG. 8, the transistor SELXA is configured to withstand a voltage that is higher than 10 volts and is capable of charging the K node at a high voltage higher than 10 volts (e.g. 15 volts). Further, the circuit shown in FIG. 8 may operate with a smaller-sized boosting capacitor than the one used in the state-of-art row driver circuitries or even without the boosting capacitor (i.e. CBOOST) for boosting the K node.

The first transistor such as the MPASS transistor is provided between K node and K′ node. The K node is coupled to a control node of a pass circuit (i.e. the gate node of the transistor indicated by MWL<X:0>). By biasing the nodes of the MPASS transistor appropriately as will be explained below, the leakage of K node is prevented more effectively than the state-of-art (i.e. FIG. 4 where a charge of the K node therein tends to leak out, as explained above). The second transistor such as the transistor MSEL is provided between the K′ node and a ground and has a gate to which a selection signal (i.e. SELa_N) is supplied. Thereby the circuit of FIG. 8 can be controlled appropriately and serve as a switching circuit.

More specifically, the circuit in FIG. 8 further includes other transistors as will be explained below. Pass transistors MWL<X:0> are shown in FIG. 8. Each of the pass transistor passes a charge between a corresponding one of the lines VXL<X:0> and a corresponding one of the lines WL<X:0>. In a flash device, plural pass transistors are provided, which are indicated by MWL<i> where i is a positive number. MWL<i> are transistors with their sources connected to the word lines and with their drains connected to VXL<i> lines. MSDG and MSSG transistors are connected with their source to SDG and SSG selection lines respectively and with their drain to GSELD and GSELS lines respectively. All the gates of MWL<i>, MSDG, MSSG transistors are connected to the same node K. Rising K node allows delivering the voltages on VXL<i>, GSELS and GSELD lines to word lines and selector lines respectively. M1 and M2 transistors are connected with their drain to SDG and SSG and with the source to ERASE line. They are driven by SELa_N signal which enables them when the block is unselected. K node is further connected by MPASS transistor to a high voltage decoding constituted by SELXA and eventually SELXB transistors connected in series between A_GVX driving line and K′ node and enable by A_HXA and A_HXB high voltage signals respectively. K′ node is in turn connected to K node by MPASS transistor controlled by A_HGVX signal on its gate. A capacitor CBOOST is eventually connected between K node and A_GBOOST driving line. MKEEP transistor is controlled by K node on its gate and connects A_GVX signal and K′ node. Further K′ node can be driven to SELa signal through MERASE transistor, gated by ERASEH signal. K′ node can be driven to ground by the series of MCASC and MSEL transistors, enabled by A_GDISCH and SELa_N signals respectively.

Any circuit element in a parenthesis [ ] is not a required circuit element for a proper implementation of the proposed row driver circuitry. Instead, those circuit elements in the parentheses may be eliminated from the proposed row driver circuitry depending on certain design specifications and technology constraints.

The basic operation of the proposed row driver circuitry shown in FIG. 8 is now explained. FIG. 9a shows an example of the driving sequence of the row driver in FIG. 8 during a program operation.

The precharging of the K-node in this proposed row driver circuitry can be triggered by raising A_HXA, A_HXB, if SELXB transistor is present, and A_HGVX. It is noted that SELXB transistor is drawn in a parenthesis [ ] and accordingly is not a required circuit element and may be eliminated as necessary. More specifically, while A_HGVX can be raised to a high voltage turning on the transistor MPASS, this raising of the A_HGVX line may be done on the address-block basis. If the raising of the A_HGVX line can be made dependent on the address block basis, the load to be charged can be reduced and accordingly, SELXB transistor can be eliminated without compromising the performance of the row driver circuit in FIG. 8.

After the K-node has precharged, both A_HXA and A_HXB may go low. The low voltage decoding may subsequently be enabled—that is, SELa_N may go high for the unselected blocks, and accordingly, the K-nodes of the unselected blocks may discharge.

It may be noted that the precharging of the K-nodes can be done exclusively through ultra-high voltage n-mos transistors. If these ultra-high voltage n-mos transistors are used to drive the K-nodes, the K-nodes may reach very high voltages such as 15V or higher depending on circumstances and technology specification. In fact, some ultra high voltage n-mos transistors may be biased with very high voltages, provided that these transistors are switched on with a voltage that does not exceed the limit of the transistors' snap-back.

Accordingly, if the proposed row driver circuitry in FIG. 8 is implemented using ultra-high voltage n-mos transistors, it may be advantageous to ensure for the safe operating area for the involved ultra-high voltage n-mos transistors. There are several ways to achieve this. In one embodiment, for example, transistor MCASC can be added to the row driver circuit as shown in FIG. 8. The transistor MCASC can be biased with an intermediate voltage between the maximum drain voltage of MSEL plus a threshold voltage and the K-node's precharging voltage (e.g., 10V). This way, the voltages may be partitioned as if transistor MCASC is acting as a cascode transistor. Accordingly, the safe operating area may be ensured for the involved transistors during discharging-phase of the K-nodes.

As shown in FIG. 9a, after A_HGVX has been lowered to VPWR, G_BOOST, GSELD, GSELS and VXL<X:0> can be raised. Accordingly, the precharging voltage of the K-nodes may be higher than it was in the case of the previously-explained state-of-art row driver circuitries. In turn, this can mean that the required amount of the boosting can be lower than in the case of the state-of-art row driver circuitries. If the required amount of the boosting can be made lower than in the case of the state-of-art row driver circuitries (e.g., circuit shown in FIG. 6), the size of the CBOOST capacitor may be smaller in the proposed row driver circuit than in the case of the state-of-art row driver circuit (e.g., shown in FIG. 6).

Furthermore, if the required amount of the boosting can be made low enough as the precharging voltage of the K-nodes is made high enough to sufficiently precharge the K-nodes, the CBOOST capacitor can be entirely eliminated from the proposed row driver circuitry.

Whether the CBOOST capacitor is reduced in size or entirely eliminated, it may produce one result—the total capacitance of the K-node can be reduced significantly. However, If the total capacitance of the K-node is reduced, there can be more likelihood of the K-node discharge due to the leakage. If the K-node leakage is less likely to occur, the reliability of the row driver circuit as a whole may significantly increase.

This is why transistor MKEEP may be introduced to the proposed row driver circuitry as shown in FIG. 8. The transistor MKEEP forces K′ node to high voltage and this reduces the drain to source voltage for transistor MPASS, and thus the nodes (i.e. K′, K, and A_HGVX) of the transistor MPASS can be biased appropriately in a point of view of preventing the leakage of K node. Since, after precharge, A_HGVX is lowered to VPWR and MKEEP transistor keeps drain to source voltage low, the leakage on K-node is almost suppressed or strongly reduced Note that this stated purpose of the transistor MKEEP is not intended to limit in any way the scope of the claimed invention.

In other words, because the gate of the transistor MPASS is biased at low voltage such as Vpwr, its gate voltage (i.e. A_HGVX) is much lower than source voltage (i.e. K′ node). Thus, sub-threshold leakage is suppressed more effectively than the state-of-art. Besides, in the case that the reduction between its drain and source (i.e. K′ node and K node) is obtained thank to MKEEP transistor, the sub-threshold leakage is further suppressed.

It may be noted that the K-node in FIG. 4 was precharged for the selected block but the transistor connected to K node has large voltage difference between its drain and source terminals (i.e. between K node and a ground), thus the leakage of K node is not prevented in FIG. 4. In general, a leakage discharges more rapidly a node with low capacity than a node with high capacity, and since no boosting capacitor is connected to K node in FIG. 4, this row driver is much more sensitive to the leakage than the proposed row driver. In the proposed row driver circuit, transistor MKEEP may ensure that the K′-node is kept at a high voltage level for the selected block even after the block selection.

The transistor MPASS can be biased with the high drain and source voltages while the gate of the transistor MPASS can be kept at the power supply level. The transistor MKEEP may be at an off-state for the unselected blocks, and accordingly, the K-nodes of the unselected blocks may be grounded. On the other hand, the transistor MKEEP may be at an on-state for the selected block, and accordingly, the K′-node of the selected block may reach the high voltage level. In particular, since MKEEP gate is connected to K-node, when K node is boosted MKEEP is allowed to pass full A_GVX voltage to K′ node (or at least K node voltage minus a threshold).

The presence of the transistor MKEEP may suppress the sub-threshold leakage of transistor MPASS, because transistor MPASS can now be the only transistor with its drain connected to the K-node and it is biased with low drain to source voltage and low gate voltage. Accordingly, a high charge retention by the K-node can be made possible. The high charge retention by the K-nodes, which means, in other words, a reduced charge leakage on the K-nodes, can enhance the reliability of the row driver circuit as a whole.

After the program operation has completed, the K-nodes may discharge through MSEL by disabling of the block decoding. In FIG. 9a, A_GVX node is supplied with 20 volts when A_GVX node charges the K′ node, but in another example, A_GVX may be supplied with 15 volts instead of 20 volts.

FIG. 9b shows an example of the driving sequence of the control signals in the row driver circuit of FIG. 8 during an erase operation. The operation of the row driver of FIG. 8 during an erase operation is now explained in more detail.

In one embodiment of the proposed row driver circuit shown in FIG. 8, transistor MERASE may be introduced. This transistor MERASE may allow connecting of the K-node to the low voltage decoding when ERASEH signal is driven to the high voltage (e.g., 10V) during an erase operation. This may allow driving of the K-node for a long time during an erase operation. For example, the K-node may be driven for the entire time period of an erase operation, as shown in FIG. 9b.

However, in this embodiment of the proposed row driver circuit (shown in FIG. 8), it may be required that the K-node be forced only to the maximum voltage equal to the power supply level, VPWR. When such is the case, it may present a limitation. For example, if the core x-path array requires a biasing that is different from being grounded or left floating during an erase operation, the row driver circuit in FIG. 8 may require that the K-node be driven to a high enough voltage to ensure that the voltage that is high enough can be passed on to the memory array. However, this may present a limitation when the voltage level that is passed on to the memory array is required to be at least equal to or higher than a certain voltage level, where this voltage level is set by the technology constraints. Then, the K-node may be required to be left floating again during an erase operation. This characteristic of the circuit may be circumvented by a second embodiment of the proposed row driver circuit, an example of which is shown in FIG. 10.

FIG. 10 shows an example of another embodiment of the proposed row driver circuit.

In a broad sense of the circuit shown in FIG. 10, the transistor SELXA is configured to withstand a voltage that is higher than 10 volts and is capable of charging the K node at a high voltage (e.g. 15 volts). Thus the K node can be precharged at the high voltage (e.g. 15 volts shown in FIG. 9a), which is higher than that of the state-of-art (i.e. 10 volts in FIG. 6 where the transistors M3 and M4 therein are not capable of charging the K node at 15 volts due to their characteristic). It is thus obtained in FIG. 10 to omit a capacitor (i.e. CBOOST) for boosting K node, or to reduce the size of the capacitor.

The first transistor such as the MPASS transistor is provided between K node and K′ node. The K node is coupled to a control node of a pass circuit (i.e. the gate node of the transistor indicated by MWL<X:0>). By biasing the nodes of the MPASS transistor appropriately as will be explained below, the leakage of K node is prevented more effectively than the state-of-art (i.e. FIG. 4 where a charge of the K node therein tends to leak out, as explained above). The second transistor such as the transistor MSEL is provided between the K′ node and a ground and has a gate to which a selection signal (i.e. SELa_N) is supplied. Thereby the circuit of FIG. 10 can be controlled appropriately and serve as a switching circuit.

More specifically, in the same way as the picture of FIG. 8, in the row driver of FIG. 10, MVX<i>, MSDG, MSSG transistors connect word lines and selector lines to VXL<i>, GSELD and GSELS lines respectively and are connected in the same way to the controlling K node. Boosting capacitor CBOOST is always connected between K node and A_GBOOST line. Also M1 and M2 transistors are connected in the same way between selector lines and ERASE line and are driven by SELa_N signal on their gate. High voltage partial decoding, instead, is now connected directly to K node and is constituted by the series of SELA and eventually SELX transistors driven on their gate by A_HXA and A_HXB signal respectively. K node is in turn connected to and elevator by the series of MPASS and MCASC transistors, gated by A_HGVX and A_GDISH signals respectively. The elevator is constituted (in the example of FIG. 10) by M3,M4,M5 and MSEL transistors. M3 and M4 are p-mos transistors connected between A_GVX high voltage line and non inverting and inverting output of the elevator, controlled by SELa_N signal in low voltage range. M3 is gated by the inverting output of the elevator and M4 is gated by the non inverting output. M4 is connected to ground by MSEL transistor, gated by the elevator control signal SELa_N. M5 is connected with its drain to the non inverting output of the elevator and the control signal. M5 gate is connected to VPWR and acts as a cascade in order to avoid voltages exceeding power supply on low voltage line SELa_N.

Any circuit element in a parenthesis [ ] is not a required circuit element for a proper implementation of the proposed row driver circuitry. Instead, those circuit elements in the parentheses may be eliminated from the proposed row driver circuitry depending on certain design specifications and technology constraints.

FIG. 11a illustrates an example of the driving sequence of the row driver in FIG. 10 during a read operation. The basic operation of the row driver circuit in FIG. 10 during a read operation is now explained. During a read operation, transistors SELXA and SELXB may be at an off-state. For example, the driving sequence of the row driver circuit of FIG. 10 during a read operation can be similar to the one for the row driver circuit shown in FIG. 6. Thus, the driving sequence shown in FIG. 11a with A_GDISCH being kept at a high voltage (e.g., 10-15V) may represent the driving sequence of the row driver circuit of FIG. 10 during a read operation. Referring to FIG. 11a, it is not specified in the picture if GBOOST is driven to selected or unselected VX voltage since both solutions are possible.

Even if the CBOOST capacitance may not be present in the row driver circuit in FIG. 10, the self-boosting mechanism can be sufficiently high enough to drive the K-node from the precharge voltage (e.g., 10V) to the required voltage value necessary to pass to the memory array the maximum voltage level required for the read operation (e.g., 6.5V). It may be noted that during a program operation, a higher voltage value may be required to be passed on to the memory array and this is achieved with higher precharge voltage.

FIG. 11b shows an example of the driving sequence of the row driver circuit in FIG. 10 during a program operation. The operation of the row driver circuit in FIG. 10 during a program operation is now explained.

The elevator A of the selected block may be enabled but may be disconnected from the K′-node and K-node by transistor MCASC that is kept at an off-state with its gate grounded. Line A_HGVX may be raised, for example, to the same voltage value for the A_GVX line (e.g., 10V). The K-node can be precharged through SELXA and SELXB transistors as previously described with respect to the proposed row driver circuitry in FIG. 8. As a consequence, the K-node can be precharged to the voltage value equal to A_HXA minus a threshold. After SELXA and SELXB are turned off, line A_GDISCH may rise, and the K-node of the unselected blocks can discharge to ground through transistor MCASC and transistor MSEL. Here, the transistors MSEL and transistor MCASC can act as cascode transistors, which in turn may ensure the safe operating area for the involved transistors.

It may be noted that when the row driver circuit of only the selected block is enabled, line A_HGVX can be discharged to power supply while GSELD, GSELS and VXL<X:0> can rise. Then, the rising of the GSELD, GSELS and VXL<X:0> lines may occur, in effect, together with CGBOOST (assuming a capacitor coupled to the A_GBOOST is present in the circuit). As previously explained with respect to the row driver circuitry in FIG. 8, the boosting capacitor represented as CBOOST in FIG. 10 is not required and may be eliminated.

As explained above, during a boosting phase the K-node can be boosted, and the voltages that are high enough can be delivered to the memory array. During a discharge phase the K-node can be forced to be driven down from A_GVX to a lower value by the rising A_HGVX and A_GDISCH. It may be noted that in FIG. 10 lines A_HGVX and A_GDISCH control connection between the K-node and the elevator A. Lastly, the driving sequence for a program operation can be terminated with A_GVX and A_HGVX being discharged to VPWR, as shown in FIG. 11a.

FIG. 11c shows an example of the driving sequence of the row driver circuit in FIG. 10 during an erase operation. FIG. 11d shows another example of the driving sequence of the row driver circuit in FIG. 10 during an erase operation.

Specifically, the operation of the row driver circuit in FIG. 10 during an erase operation is now explained. During an erase operation, signals A_HXA and A_HXB can be grounded while A_HGVX and A_GDISCH that are biased to the high voltage level would connect the elevator to the K-node. As explained above, the K-node may be driven for the entire period of an erase operation. Depending on the voltage level required for the K-node to properly bias the word lines and selector lines, the driving sequence of the proposed row driver circuit in FIG. 10 during an erase operation can be either FIG. 11c or FIG. 11d. Of course, the driving sequence can take any other forms, depending on other design and technology constraints, as it would be obvious to one of ordinary skill in the art.

In FIG. 11c, the K-node can be biased to the power supply level as the maximum voltage to be delivered onto the memory array can be ground. The selectors may be left floating since MSDG and MSSG may be at an off-state, as their gates can be biased to VPWR and their sources (GSELD and GSELS, respectively) also biased to VPWR while their drains can be boosted by the matrix well-coupling.

In FIG. 11d, the K-node can be biased to A_GVX which is a high voltage (e.g., 10V), and this may allow biasing of the selectors to a higher voltage (e.g., 7.5V) than in FIG. 11b. This may be possible because the selectors can be biased directly from GSELD and GSELS through MSDG and MSSG transistors which are kept at an on-state. This configuration may allow delivering to the memory array a bias voltage higher than ground, if necessary, during an erase operation.

It may be possible to apply the above explained concept to design a variety of different row driver circuitries with obvious modifications, for example, to satisfy particular design limitations and any technology constraints.

Further, it may be possible to generate different driving sequence of the proposed row driver circuitries than the ones shown in, for example, FIGS. 9a-9b and 11a-11d. The illustrated driving sequences are just for the convenience of the description and should not be used to limit in any way the scope of the proposed row driver circuitries and its applications to different technologies and design specifications with obvious modifications.

One skilled in the relevant art will recognize that many other possible modifications and combinations of the disclosed embodiments can be used, while still employing the same basic underlying mechanisms and methodologies. The foregoing description, for purposes of explanation, has been written with references to specific embodiments. However, the illustrative discussions above are not intended to be exhaustive or to limit the disclosure to the precise forms disclosed. Many modifications and variations can be possible in view of the above teachings. The embodiments were chosen and described to explain the principles of the disclosure and their practical applications, and to enable others skilled in the art to utilize the disclosure and various embodiments with various modifications as suited to the particular use contemplated.

Furthermore, while this specification contains many specifics, these should not be construed as limitations on the scope of what is being claimed or of what may be claimed, but rather as descriptions of features specific to particular embodiments. Certain features that are described in this specification in the context of separate embodiments can also be implemented in combination in a single embodiment. Conversely, various features that are described in the context of a single embodiment can also be implemented in multiple embodiments separately or in any suitable subcombination. Moreover, although features may be described above as acting in certain combinations and even initially claimed as such, one or more features from a claimed combination can in some cases be excised from the combination, and the claimed combination may be directed to a subcombination or variation of a subcombination.

What is claimed is:

1. A device comprising:
a first transistor having a source-drain path coupled between a first node and a second node, the first node being coupled to a control node of a pass circuit;
a second transistor coupled between the second node and a ground, having a gate to which a selection signal is supplied; and
a voltage-charging circuit including a third transistor configured to withstand a voltage that is higher than 10 volts to charge the first node.

2. The device of claim 1, wherein the pass circuit is configured to convey a charge to a memory array in response to a level produced at the control node.

3. The device of claim 1, wherein the third transistor of the voltage-charging circuit is coupled to the second node to charge the first node.

4. The device of claim 3, further comprising:
a fourth transistor coupled in parallel to the source-drain path of the third transistor, the fourth transistor having a gate coupled to the first node,
a fifth transistor coupled between a fifth node to which an inverted one of the selection signal is supplied and the second node, the fifth transistor having a gate to which an erase signal is supplied.

5. The device of claim 1, further comprising:
a voltage line coupled to a gate of the first transistor and configured to change in a voltage level between the ground potential and a first potential which is higher than the ground potential.

6. The device of claim 5, wherein the voltage-generating circuit charges the first node when or after the voltage line has changed in a voltage level from the ground potential to the first potential.

7. The device of claim 5, wherein the voltage line changes in a voltage level from the first potential to a second potential which is lower than the first potential and higher than the ground potential, after the voltage-charging circuit has charged the first node.

8. The device of claim 1, further comprising:
a charge-selecting line coupled to a gate of the third transistor of the voltage-charging circuit, the charge-selecting line taking a first level to render the third transistor conductive when the voltage-generating circuit charges the first node and taking a second level different from the first level such that the voltage-generating circuit refrains from charging the first node.

9. The device of claim 1, wherein the third transistor of the voltage-charging circuit is coupled to the first node to charge the first node.

10. The device of claim 9, further comprising:
a fourth transistor positioned between the second node and the second transistor and having a source-drain path between the second node and one end of the second transistor;
a voltage-supplying line;
a fifth transistor coupled between the voltage-supplying line and the one end of the second transistor;
a sixth transistor coupled between the voltage-supplying line and a third node and having a gate coupled to the one end of the second transistor; and
a seventh transistor coupled between the third node of the sixth transistor and the gate of the second transistor.

11. The device of claim 1, wherein the pass circuit includes:
an n-mos transistor coupled to a word line and having a gate coupled to the first node of the first transistor.

12. The device of claim 1, further comprising:
a capacitor having a first end coupled to the first node and a second end supplied with a boosting signal.

13. The device of claim 1, wherein the voltage-charging circuit charges the first node at a voltage level that is higher than 10 volts.

14. A device comprising:
a non-volatile memory array coupled to a data line;
a data line driver driving the data line to a selection level, the data line driver comprising;
a first transistor coupled between a first node and a second node and a gate coupled to a first voltage line;
a second transistor coupled between the second node of the first transistor and a ground and having a gate coupled to a selection signal;
a third transistor coupled between a second voltage line and the second node of the first transistor and having a gate coupled to a first control signal;
a fourth transistor coupled between the second voltage line and the second node of the first transistor and having a gate coupled to the first node of the first transistor, and
a fifth transistor coupled between a fourth node to which an inverted one of the selection signal is supplied and the second node of the first transistor, the fifth transistor having a gate coupled to an erase signal.

15. The device of claim 14, the data line driver further comprising:
a sixth transistor coupled between the third transistor and the second node of the first transistor and having a gate to which a second control signal is supplied; and
a seventh transistor coupled between the second node of the first transistor and the second transistor and having a gate to which a discharge signal is supplied.

16. The device of claim 14, further comprising:
a pass circuit coupled to the data line and having a control node coupled the first node of the first transistor of the data line driver.

17. The device of claim 14, the data line driver further comprising:
a capacitor having a first end coupled to the first node and a second end supplied with a boosting signal.

18. A device comprising:
a non-volatile memory array coupled to a data line;
a data line driver driving the data line to a selection level, the data line driver comprising;
a first transistor coupled between a first node and a second node and having a gate coupled to a first voltage line;
a second transistor coupled between the second node of the first transistor and a third node and having a gate to which a discharge signal is supplied;
a third transistor coupled between the third node of the second transistor and a ground and having a gate coupled to which a selection signal is supplied;
a fourth transistor coupled between a second voltage line and the first node of the first transistor and having a gate to which a first control signal is supplied;
a fifth transistor coupled between a third voltage line and a fourth node and having a gate coupled to the third node of the second transistor; and
a sixth transistor coupled between the third voltage line and the third node of the second transistor and having a gate coupled to the fourth node of the fifth transistor;
a seventh transistor coupled between the fourth node of the fifth transistor and the gate of the third transistor and having a gate to which a fourth voltage line is supplied; and
a eight transistor coupled to the data line and having a gate coupled the first node of the first transistor.

19. The device of claim 18, the data line driver further comprising:
a ninth transistor inserted between the fourth transistor and the first node and having a gate to which a second control signal is supplied.

20. The device of claim 18, the data line driver further comprising:
a capacitor having a first end coupled to the first node and a second end supplied with a boosting signal.
